(19) United States
(12) Patent Application Publication
(10) Pub. No.: US 2026/0016798 A1
(43) Pub. Date: Jan. 15, 2026

(54) DATABASE FOR IMPLEMENTING REAL-TIME DIGITAL TWIN SYSTEM AND SYSTEM FOR CREATING DIGITAL TWIN

(71) Applicant: SIMACRO INC., Seoul (KR)

(72) Inventors: Jeong Ho YUN, Lexington, MA (US); Wang Soo KIM, Seoul (KR); Elijah PARK, Seoul (KR); Hyeon Jun JO, Seoul (KR)

(21) Appl. No.: 19/330,853

(22) Filed: Sep. 17, 2025

Related U.S. Application Data
(63) Continuation of application No. PCT/KR2024/000747, filed on Jan. 16, 2024.

(30) Foreign Application Priority Data
Mar. 17, 2023 (KR) 10-2023-0035336
Jul. 18, 2023 (KR) 10-2023-0093173

(51) Int. Cl. G05B 13/04; G06F 16/215; G06F 16/23; G06F 16/2458; G06F 30/20

(52) U.S. Cl. CPC G05B 13/048; G06F 16/215; G06F 16/23; G06F 16/2462; G06F 30/20

(57) ABSTRACT

Provided are a database (DB) for implementing a real-time digital twin system, and a system for creating a digital twin. The DB includes a first DB configured to receive data from a legacy DB and store refined data that has undergone primary data processing, and a second DB configured to store model parameter update data that is derived by inputting the refined data stored in the first DB into a steady state determination module.

### CROSS-REFERENCE TO RELATED APPLICATION

This application is a U.S. Bypass Continuation Application of International Application No. PCT/KR2024/000747, filed on Jan. 16, 2024, which claims priority to and the benefit of Korean Patent Application No. 10-2023-0035336, filed on Mar. 17, 2023, and Korean Patent Application No. 10-2023-0093173, filed on Jul. 18, 2023, the disclosure of which is incorporated herein by reference in its entirety.

### BACKGROUND

### Technical Field

The present invention relates to a database (DB) for operating a real-time digital twin system and a digital twin creation system.

### Discussion of Related Art

A digital twin refers to a technology for visualizing a physical system in a digital form using measurable data as if it were a twin. With a digital twin, not only measured data but also values calculated by simulation can be viewed directly in real time on a two-dimensional (2D) screen or through three-dimensional (3D) imagery. By digitizing and representing the key variables of a physical system, it is possible to analyze the current state of the system, predict future behavior, and even prevent potential hazards such as an explosion in a chemical process. Like this, digital twins are primarily used to effectively monitor, manage, and control systems and also utilized in factory design, construction, and optimization.

In factories and plants, legacy databases (DBs) for managing data sensed by limited sensors have been traditionally used. Data stored in these legacy DBs is an important resource for factory and plant operations, but there are limitations in terms of optimization for the construction of digital twins and smart factories. Also, general digital twin technology updates data received from smart factories and other facilities discontinuously at regular intervals, making it difficult to reflect changes in digital twins in real time. In addition, since a model that has already been determined is utilized to create a digital twin, changes made to equipment are difficult to reflect in the model.

In connection with the above issues, the present invention aims to provide a DB architecture suitable for real-time digital twin modeling.

### SUMMARY OF THE INVENTION

An object to be achieved by the technical spirit of the present disclosure is to provide a database (DB) for operating a real-time digital twin system and a digital twin creation system.

According to the technical spirit of the present disclosure, there is provided a DB for implementing a real-time digital twin system, the DB including a first DB configured to receive data from a legacy DB and store refined data that has undergone primary data processing, and a second DB configured to store model parameter update data that is derived by inputting the refined data stored in the first DB into a steady state determination module.

The first DB may perform the primary data processing on plant data generated by sensing a target facility that is a target of a digital twin stored in the legacy DB.

Abnormal data may be removed through the primary data processing.

The second DB may receive a plurality of pieces of plant data sequentially measured over time during a first period, calculate a variation value of the plurality of pieces of plant data, determine whether the variation value is a predetermined value or less, and when the variation value is the predetermined value or less, determine that the plurality of pieces plant data are in a steady state and store steady state determination information.

The second DB may calculate a mean value of the plurality of pieces of plant data through a parameter updater module, acquire parameters from a prediction model using the calculated mean value, and store the acquired parameters as updated parameters to be applied to the prediction model.

The steady state determination module may receive the plant data at intervals of a second period, which may be shorter than the first period.

The steady state determination module may collect the plurality of pieces of plant data by collecting N (N is a natural number of 2 or more) pieces of the plant data, which correspond to the first period, collected every second period, and the parameter updater module may calculate a mean value of the plurality of pieces of plant data, acquire parameters from a prediction model using the calculated mean value, and update the second DB with the parameters by applying the acquired parameters to the prediction model.

The DB may further include a third DB configured to store model prediction data that is derived by inputting the refined data into a dynamic state model in which updated model parameters are reflected.

A result of receiving the data from the legacy DB and generating reference prediction data may be separately stored in the third DB.

The reference prediction data and the model prediction data stored in the third DB may be compared to verify a data processing part.

According to the technical spirit of the present disclosure, there is provided a system for creating a digital twin including at least one processor, the system including a data processing part configured to receive sensing data from a legacy DB and remove noise, a steady state determination part configured to determine whether plant data generated by sensing a target facility that is a target of a digital twin is in a steady state, a parameter updater configured to acquire parameters by applying the plant data to a prediction model when the plant data is in a steady state, and apply the acquired parameters to the prediction model, a prediction data generator configured to generate prediction data by inputting the plant data into the prediction model of which the parameters are updated, and a DB part including a first DB configured to store refined data derived by the data processing part, a second DB configured to store the parameters acquired by the parameter updater, and a third DB configured to store the prediction data generated by the prediction data generator.

According to the technical spirit of the present disclosure, there is provided a digital twin creation server, comprising: a memory storing a first database (DB1), a second database (DB2), and a third database (DB3) in mutually distinct address ranges; and at least one processor configured to: (a) obtain sensor measurements from a plurality of sensors of a target facility at a second period (P2); (b) compute a P2-mean for each process variable and write the P2-means to DB1; (c) maintain a sliding window of length P1=N×P2 (N≥2), compute a variance over the window, compare the variance with sensor-specific thresholds stored in the memory, and classify the window as steady state only when the comparison is satisfied for M consecutive windows (M≥2), and record steady-state information in DB2; (d) when the window is steady, compute a window mean and solve mass-balance and energy-balance equations to acquire a parameter vector (PR) for a prediction model, and write PR with a timestamp and a window identifier to DB2; (e) evaluate a dynamic-state model using PR and the plant data to generate prediction data (SD) including at least one unmeasured state variable, and write SD to DB3 together with an identifier of PR used; and (f) execute (c)-(e) asynchronously with respect to (a)-(b) to avoid contention and to meet real-time latency for visualization and control.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a block diagram of a digital twin creation system according to an exemplary embodiment of the present disclosure;

FIG. 2 is a block diagram showing a digital twin creation server according to an exemplary embodiment of the present disclosure;

FIG. 3 is a flowchart showing a digital twin creation method according to an exemplary embodiment of the present disclosure;

FIG. 4 is a diagram showing a digital twin creation method according to the exemplary embodiment of the present disclosure;

FIG. 5 is a table showing a steady state determination method according to an exemplary embodiment of the present disclosure;

FIG. 6 is a flowchart showing the digital twin creation method according to the exemplary embodiment of the present disclosure;

FIG. 7 is a view of a digital twin according to an exemplary embodiment of the present disclosure; and

FIG. 8 is a block diagram showing a digital twin creation server according to an exemplary embodiment of the present disclosure.

### DETAILED DESCRIPTION OF EXEMPLARY EMBODIMENTS

A database (DB) includes a first DB configured to receive data from a legacy DB and store refined data that has undergone primary data processing, and a second DB configured to store model parameter update data that is derived by inputting the refined data stored in the first DB into a steady state determination module.

Hereinafter, exemplary embodiments of the present disclosure will be described in detail with reference to the accompanying drawings. Advantages and features of the present invention and methods of achieving them will become apparent with reference to exemplary embodiments described in detail below in conjunction with the accompanying drawings. However, the technical spirit of the present disclosure is not limited to the embodiments disclosed below but may be implemented in various different forms, and the embodiments are only provided to make the technical spirit of the present disclosure complete and fully convey the scope of the present disclosure to those of ordinary skill in the art to which the present disclosure pertains. The technical scope of the present disclosure is only defined by the scope of claims.

When assigning reference numerals to components of each drawing, it is to be noted that the same components have the same reference numeral even if they are shown in different drawings. In addition, when describing the present disclosure, detailed description of related known components or functions will be omitted if it is deemed to obscure the subject matter of the present disclosure.

Unless otherwise defined, all terms used herein (including technical or scientific terms) may be used with the same meanings as commonly understood by those of ordinary skill in the technical field to which the present disclosure pertains. Terms such as those defined in commonly used dictionaries are not construed as having an idealized or unduly formal meaning unless expressly defined. Terminology used herein is intended to describe embodiments and is not intended to limit the present disclosure. In this specification, singular expressions include plural expressions unless context clearly indicates otherwise.

Also, in the description of components of the present disclosure, terms such as “first”, “second”, “A”, “B”, “(a)”, “(b)”, etc., may be used. These terms are used only for the purpose of discriminating one component from another component, and the nature, the sequence, the order, etc., of the components are not limited by the terms. It is to be noted that, when one component is described as being “connected,” “coupled,” or “joined” to another component, the former may be directly “connected,” “coupled,” or “joined” to the latter, or still another component may be “connected,” “coupled,” or “joined” between the components.

As used herein, the term “comprises” and/or “comprising” does not exclude the presence or addition of one or more components, steps, operations, and/or elements other than stated components, steps, operations, and/or elements.

Components included in one embodiment and components having a common function will be described using the same names in other embodiments. Unless otherwise described, the description of any one embodiment is applicable to other embodiments, and detailed descriptions may be omitted within the scope of overlap or the scope that can be readily understood by those skilled in the art.

Hereinafter, the present invention will be described in detail with reference to exemplary embodiments of the present invention and the accompanying drawings.

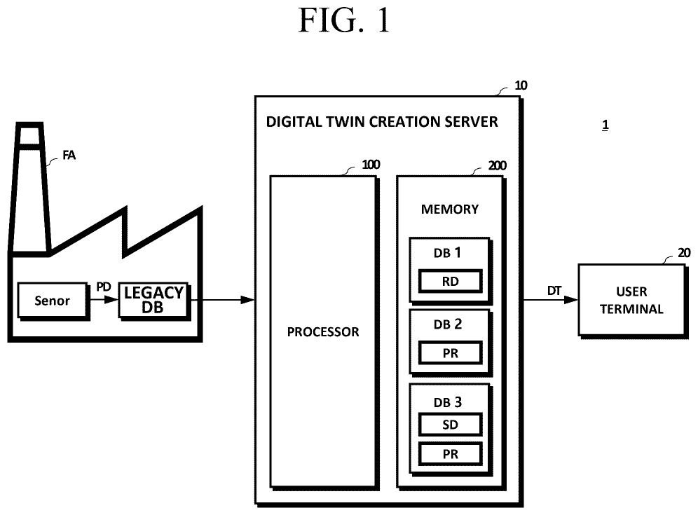

FIG. 1 is a block diagram of a digital twin creation system according to an exemplary embodiment of the present disclosure.

Referring to FIG. 1, a digital twin creation system 1 may create a digital twin DT on the basis of refined data RD received from a legacy DB storing plant data PD sensed from a target facility FA and provide the digital twin DT to a user terminal 20. To this end, the digital twin creation system 1 may include a digital twin creation server 10 and the user terminal 20.

Components of the digital twin creation system 1 may be connected by wire or wirelessly to communicate with each other. When connected by wire, the components of the digital twin creation system 1 may perform serial communication. When connected wirelessly, the components of the digital twin creation system 1 may communicate with each other using a wireless communication network, which includes, but is not limited to, a local area network (LAN), a wide area network (WAN), the Internet (the World Wide Web (WWW)), a wired/wireless data communication network, a telephone network, a wired/wireless television communication network, a 3^{rd} Generation (3G) network, a 4th Generation (4G) network, a 5th Generation (5G) network, a 3^{rd} Generation Partnership Project (3GPP) network, a 5th Generation Partnership Project (5GPP) network, a Long Term Evolution (LTE) network, a World Interoperability for Microwave Access (WIMAX) network, a Wi-Fi network, an Internet network, a wireless LAN, a wide area network (WAN), a personal area network (PAN), a radio frequency (RF) network, a Bluetooth network, a near-field communication (NFC) network, a satellite broadcast network, an analog broadcast network, a digital multimedia broadcasting (DMB) network, and the like.

The target facility FA is a facility which is a target of the digital twin DT. For example, the target facility FA may include a factory, machinery, equipment, objects, etc., for performing a chemical process. In the target facility FA, sensors (e.g., a temperature sensor, a pressure sensor, a flow sensor, etc.) for sensing various characteristics of the target facility FA may be installed, and the sensors may generate the plant data PD by measuring various characteristics (e.g., a temperature of a specific part of the facility, an internal pressure of the facility, and a rate of flow in the facility) of the target facility FA. Also, according to embodiments, the plant data PD may further include not only data measured by the sensors but also data (e.g., a concentration, the number of moles, etc., of a material input into the facility) input by an operator of the target facility FA.

The digital twin creation server 10 may include a variety of components used for creating the digital twin DT. The digital twin creation server 10 may be implemented by a server (including a cloud server that is run online) or various terminal devices including a personal computer (PC), a cellular phone, a smartphone, a laptop, a navigation device, a personal communication system (PCS) terminal, a Global System for Mobile communications (GSM) device, a personal digital cellular (PDC) terminal, a personal handy-phone system (PHS) terminal, a personal digital assistant (PDA) terminal, an International Mobile Telecommunication (IMT)-2000 terminal, a code division multiple access (CDMA)-2000 terminal, a wideband code division multiple access (W-CDMA) terminal, a WiBro terminal, a smartpad, and a tablet PC.

The digital twin creation server 10 may include a processor 100 and a memory 200. The processor 100 may perform a variety of operations to create the digital twin DT using a first DB DB1, a second DB DB2, and a third DB DB3 stored in the memory 200. The memory 200 may store various kinds of data (e.g., the raw plant data PD, the refined plant data RD, prediction data SD, and parameters PR) required for creating the digital twin DT. As an example, the processor 100 may include at least one of a central processing unit (CPU), a graphics processing unit (GPU), a neural processing unit (NPU), a random access memory (RAM), a read-only memory (ROM), a system bus, and an application processor, and the memory 200 may include a non-volatile memory, a volatile memory, a flash memory, a hard disk drive (HDD), a solid state drive (SSD), or the like. The processor 100 and the memory 200 may be hardware components.

In this specification, operations of the digital twin creation server 10 or components therein may be operations performed by the processor 100 on the basis of a computer program including at least one instruction stored in the memory 200.

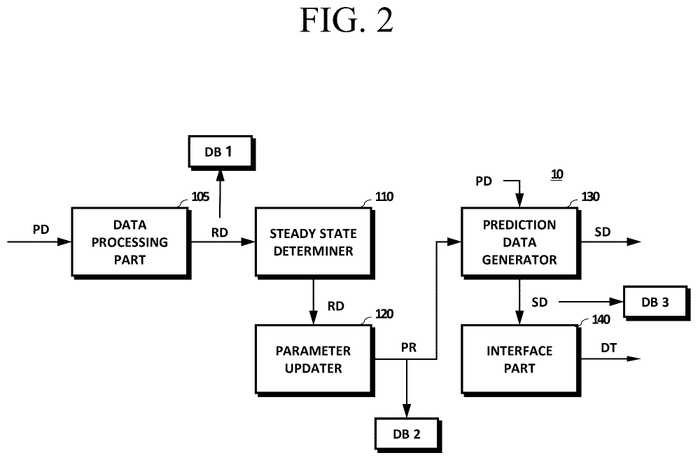

The processor 100 may receive the plant data PD stored in the legacy DB of the target facility FA and perform primary data processing thereon. Specifically, the data processing may also be performed by a data processing part (150 of FIG. 2) controlled by the processor 100, and the refined plant data RD may be stored in the first DB DB1 of the memory 200. Also, the processor 100 may generate the prediction data SD by inputting the refined plant data RD into a prediction model to which the parameters PR are applied. The parameters PR may be stored in the second DB DB2, and the prediction data SD may be stored in the third DB DB3. According to the exemplary embodiment, the first DB DB1, the second DB DB2, and the third DB DB3 may be separately managed by the processor 100 and stored in different areas (e.g., at different addresses) of the memory 200. Alternatively, the first DB DB1, the second DB DB2, and the third DB DB3 may be stored in separate hardware storages and are not limited to the above-described embodiment.

According to the exemplary embodiment of the present disclosure, the processor 100 may update the parameters PR on the basis of the refined plant data RD. Accordingly, changes in the parameters PR due to changes in the refined plant data RD may be reflected in real time in the prediction model, and changes in the target facility FA may also be reflected in real time in the digital twin DT. The updated parameters PR may be stored in not only the second DB DB2 but also the third DB DB3 together with the corresponding prediction data SD. In the second DB DB2, the history of parameter changes before and after the parameters PR are updated may be checked. In the third DB DB3, a set of the prediction data SD and the parameters PR corresponding thereto is stored, and thus information on from which parameters the prediction data SD has been derived may be clearly managed.

According to the exemplary embodiment of the present disclosure, the processor 100 may determine whether the refined plant data RD is in a steady state, and update the parameters PR using the refined plant data RD in a steady state. In this specification, a steady state means a state that a system or component ultimately reaches when external inputs to the system or component do not change (are not transient) and remain at constant values. Accordingly, changes in the parameters PR due to changes in the refined plant data RD may be reflected in real time in the prediction model, and changes in the target facility FA may also be reflected in real time in the digital twin DT.

The user terminal 20 may include a variety of components that are utilized to check or control various kinds of data of the target facility FA through the digital twin DT, and may be implemented by various terminal devices including a PC, a cellular phone, a smartphone, a laptop, a navigation device, a PCS terminal, a GSM device, a PDC terminal, a PHS terminal, a PDA terminal, an IMT-2000 terminal, a CDMA-2000 terminal, a W-CDMA terminal, a WiBro terminal, a smartpad, and a tablet PC.

FIG. 2 is a block diagram showing a digital twin creation server according to an exemplary embodiment of the present disclosure.

Referring to FIG. 2, the digital twin creation server 10 may include a data processing part 105, a steady state determination module 110, a prediction data generator 130, a parameter updater 120, and an interface part 140. The data processing part 105, the steady determination module 110, the prediction data generator 130, the parameter updater 120, and the interface part 140 may be software modules delimited by functions that are performed on the basis of the computer program stored in the memory 200 by the processor 100 included in the digital twin creation server 10, and operations performed by the data processing part 105, the steady determination module 110, the prediction data generator 130, the parameter updater 120, and the interface part 140 may be performed through separate software modules and a plurality of pieces of hardware or one piece of hardware.

In the illustrated implementation, the memory 200 maintains a first database DB1 for raw/aggregated plant data (e.g., P2 means with timestamps) and a second database DB2 for derived artifacts such as the parameter vectors PR and the prediction data SD. The separation allows for independent retention policies (e.g., longer retention for PR/SD to support model validation) and enables low-latency reads by the prediction data generator 130. The processor 100 may execute the steady-state determination and parameter update asynchronously with respect to the P2 acquisition, thereby avoiding contention and ensuring that visualization and control tasks meet real-time constraints.

The data processing part 105 may receive plant data PD from a legacy DB in which raw data directly measured by a sensor of a plant is stored, and primarily process the plant data PD. Even when data is measured directly from the sensor of the plant, unreliable data due to sensor abnormalities or data abnormalities may be included in the plant data PD. Accordingly, the data processing part 105 primarily processes the raw data into reliable refined data. For example, the data processing part 105 may generate refined plant data RD by determining data that has changed to a physically/chemically impossible level or abnormal data in the trend of the plant data PD as noise and removing the data. A reliable digital twin DT may be created using the refined plant data RD rather than the plant data PD as basic data. Also, the original plant data PD may be stored in a legacy DB or in a first DB in parallel such that the data processing part 105 may acquire reliable refined plant data RD by processing the data. To verify and improve a data processing process of the data processing part 105, a first digital twin DT may be created on the basis of the raw plant data PD, and a second digital twin DT may be created on the basis of the refined plant data RD. Then, by comparing the actual plant data with the first and second digital twins DT, a feedback system may be configured to improve the reliability of the refined plant data RD and improve the processing method. To this end, reference prediction data that is derived by passing the raw plant data PD not through the data processing part 105 but through a steady state determination module 110, the parameter updater 120, the prediction data generator 130, and the interface part 140 may be separately stored in the third DB DB3. The reference prediction data may be compared with prediction data SD derived from the refined plant data RD and verified. Specifically, the reference prediction data may be compared directly within a data group. Preferably, digital twins based on the prediction data are separately created (the first digital twin (created on the basis of RD) and the second digital twin (created on the basis of PD)) and compared with each other, or reliable actual plant data for verification may be provided for precise comparison.

For example, when both the first digital twin and the second digital twin have a large error compared to the actual plant situation, the steady state determination module 110 and the prediction data generator 130 may be improved. However, when it is determined that unreliable data is included in data underlying the problem, a data processing method may be tuned to make refined data of the data processing part 105 more reliable. This may mean improving the processing process such that data of the second digital twin is close to the actual plant data, which is reference data for verification, within the margin of error.

For example, when the first digital twin is more similar to the actual plant data than the second digital twin, it may be determined that the data processing part 105 is processing unreliable basic data. In this case, the data processing part 105 may determine reliable data as unreliable data and remove the data or verify whether processing unrelated to actual data has occurred in a data normalization task, etc., to improve the processing process of the data processing part 105.

The steady state determination module 110 may receive the refined plant data RD and determine whether the plant data PD is in a steady state. As an example, the steady determination module 110 may acquire the refined plant data RD by reading the refined plant data RD stored in the first DB DB1. According to the exemplary embodiment, the steady determination module 110 may receive a plurality of pieces of refined plant data RD corresponding to different time points and determine whether the refined plant data RD is in a steady state on the basis of whether a variance value of the refined plant data RD is a predetermined value or less. According to the exemplary embodiment of the present disclosure, it is possible to determine whether the refined plant data RD is data in a steady state simply and accurately by determining whether the refined plant data RD is in a steady state on the basis of variance, and as a result, parameters PR corresponding to the accurate refined plant data PD can be determined.

The parameter updater 120 may determine the parameters PR on the basis of the refined plant data RD in a steady state. According to the exemplary embodiment, the parameter updater 120 may determine the parameters PR by applying a mean value of the plurality of pieces of refined plant data RD to a prediction model. According to the exemplary embodiment of the present disclosure, when the mean value of the refined plant data RD is used to determine the parameters PR, the refined plant data RD can be updated to reflect a state of a target facility FA during a predetermined period, and the accurate state of the target facility FA can be reflected in the prediction model. The parameters PR may be stored in the second DB DB2.

As an example, the parameter updater 120 may receive, as the refined plant data RD, pressure difference values, measured temperature values, and measured rate-of-flow values at specific point of the target facility FA and obtain a reaction rate constant, the amount of coke, and a heat transfer coefficient as the parameters PR by applying the received pressure difference values, measured temperature values, and measured rate-of-flow values to predetermined formulae.

When a window is classified as steady state, the parameter updater 120 computes a window mean of relevant plant data (e.g., temperature Tamb, flow rate F, pressure difference at a measured location) and obtains a parameter vector PR for the prediction model. In an exemplary chemical-process embodiment, PR includes at least one of a reaction rate constant (k0), a coke amount (Mcoke), and a heat-transfer coefficient (U). The parameter updater 120 may determine PR by solving or numerically minimizing mass-balance and energy-balance equations that relate the window mean inputs to process outputs as described herein (see, e.g., Equation (1)). The updated parameter vector PR is written to the second database DB2 together with a timestamp and the corresponding window identifier, enabling versioned replay of the digital twin for auditing and model-drift analysis.

If the steady-state gate is not satisfied for a prolonged period (e.g., due to frequent grade changes or start-up), the parameter updater 120 defers updates and continues to use the last valid parameter vector PR*, thereby preventing contamination of the prediction model by transient or noisy data.

The prediction data generator 130 may generate the prediction data SD by inputting the refined plant data RD stored in the first database DB1 into the prediction model to which the parameters PR determined by the parameter updater 120 are applied. The prediction data generator 130 may store the generated prediction data SD in the third database DB3 of the memory 200.

As described above, for verification by the data processing part 105 or process improvement, the prediction data generator 130 may generate verification prediction data (not shown) by inputting raw plant data PD stored in the legacy DB or the first DB DB1 into the prediction model reflecting the parameters PR determined by the parameter updater 120.

The processor 100 may improve and verify a data processing procedure of the data processing part 105 using a feedback system that compares the three sides on the basis of the verification prediction data, the prediction data SD, and the actual plant data which is a reference for verification.

As an example, the refined plant data RD received by the prediction data generator 130 may include a measured temperature value T_{amb} and a measured rate-of-flow value F at a specific point of the target facility FA, and the updated parameters PR may include a reaction rate constant k0, the amount of coke Mcoke, and a heat transfer coefficient U. When ΔP is a predicted pressure difference, T_{tube} is a temperature at an unmeasurable point, and Cmol1 and Cmol2 are the numbers of moles of compositions, the prediction data SD may be generated by a prediction model corresponding to Equation 1 below (in the following equation, r_{coke} is a coke generation rate, Ea is a constant, tₙ is a current time point, tₙ₋₁ is a previous time point, Δt=tₙ−tₙ₋₁, A_{tube} is the area of a tube installation, and Q is total calories).

$$\begin{matrix}{r}_{coke} = k [ C mol 1 ] [ C mol 2 ] \\ k = k 0 * exp ( - \frac{Ea}{{T}_{tube}} ) \\ {M}_{coke} ( {t}_{n} ) = {M}_{coke} ( {t}_{n - 1} ) + {r}_{coke} * Δ t \\ Δ P = f ( {A}_{tube} , F ) \\ {A}_{tube} = f ( {M}_{coke} ) \\ Q = U * ( T - {T}_{tube} ) * {A}_{tube}\end{matrix} \qquad [ Equation 1 ]$$

The prediction data generator 130 receives the current plant data PD (e.g., Tamb and F) and the updated parameters PR and evaluates the prediction model to produce prediction data SD. In the illustrated embodiment, SD includes at least one unmeasured variable such as a tube-wall temperature Ttube, a predicted pressure drop (ΔP), and composition mole numbers (Cmol1, Cmol2). The model may be evaluated in discrete time with step size Δt=tn−tn−1 and may incorporate accumulated terms such as a coke generation rate r_{coke} and total heat Q, as set forth in Equation (1). The generated prediction data SD is stored in the second database DB2 for subsequent visualization, control, and traceability.

The interface part 140 may reflect the prediction data SD in an interface to create the digital twin DT. As an example, the prediction data SD may include temperature information of an unmeasurable point, and the interface part 140 may create a digital twin by changing the color of the unmeasurable point on the basis of the temperature information included in the prediction data SD.

In certain embodiments, the interface part 140 not only updates a visualization of the digital twin DT but also provides a control interface to the target facility FA. The interface part 140 compares selected elements of the prediction data SD (for example, Ttube or ΔP) against predefined operating limits and safety limits maintained in the memory 200. When a violation or a projected deviation beyond a configured margin is detected, the interface part 140 generates a control command that, when executed by a controller of the target facility (e.g., PLC/DCS), actuates one or more physical actuators such as a valve, a heater, or a pump to adjust a process condition. The control command may encode a setpoint or a rate-of-change directive and may be transmitted over a wired or wireless industrial communication network. In one example, an over-temperature prediction for an unmeasured region triggers a staged decrease of heater power combined with an increase in coolant flow; after the variables return within a safe band, the interface part 140 automatically reverts to nominal setpoints. This closed-loop action integrates the prediction model into real-time plant operation, thereby improving safety and stability.

To enhance robustness, the interface part 140 may implement failsafe policies, including: (i) aborting transmission when integrity checks fail; (ii) clamping setpoints to equipment-specific bounds; and (iii) recording acknowledgements and outcomes of control actions in the second database DB2 to support audit and recovery.

According to an exemplary embodiment of the present disclosure, the digital twin creation server 10 updates the parameters PR of the prediction model on the basis of the refined plant data RD in a steady state and generates the prediction data SD on the basis of the updated parameters PR. Accordingly, information on the target facility FA in an accurate state can be reflected in the prediction model for creating a digital twin, and as a result, it is possible to create a digital twin that is synchronized with the target facility FA in real time. In addition, since the raw plant data PD coexists and is managed in a DB, it is possible to create a preliminary digital twin that allows management and verification by the data processing part, which enables a user to efficiently create and verify a digital twin DT.

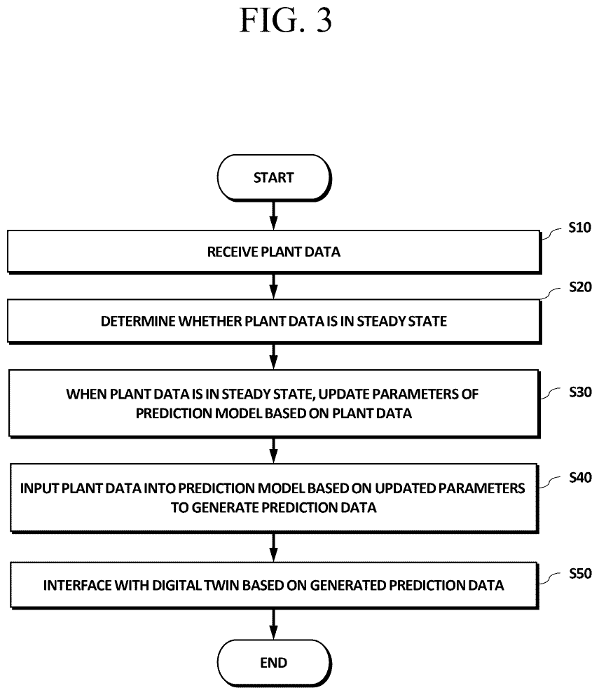

FIG. 3 is a flowchart showing a digital twin creation method according to an exemplary embodiment of the present disclosure.

Referring to FIG. 3, the digital twin creation server 10 may receive plant data PD from a target facility FA (S10) and determine whether the plant data is in a steady state (S20). According to the exemplary embodiment, the digital twin creation server 10 may determine whether the plant data PD is in a steady state on the basis of whether a variance value of the refined plant data RD is a predetermined value or less

When the plant data PD is in a steady state, the digital twin creation server 10 may update parameters PR of a prediction model on the basis of the refined plant data RD (S30). According to the exemplary embodiment, the digital twin creation server 10 may acquire the parameters PR from the prediction model using a mean value of the refined plant data RD.

The digital twin creation server 10 may generate prediction data SD by inputting the refined plant data RD into the prediction model based on the updated parameters PR (S40). The digital twin creation server 10 may create a digital twin by interfacing with the digital twin on the basis of the prediction data SD (S50).

With the digital twin creation method according to the technical spirit of the present disclosure, parameters PR are updated on the basis of the refined plant data RD in a steady state such that a value of the refined plant data RD corresponding to a case where inputs from a target facility FA are in a steady state can be reflected in a prediction model. As a result, noise is removed, and accurate information on the target facility FA can be reflected in a digital twin in real time.

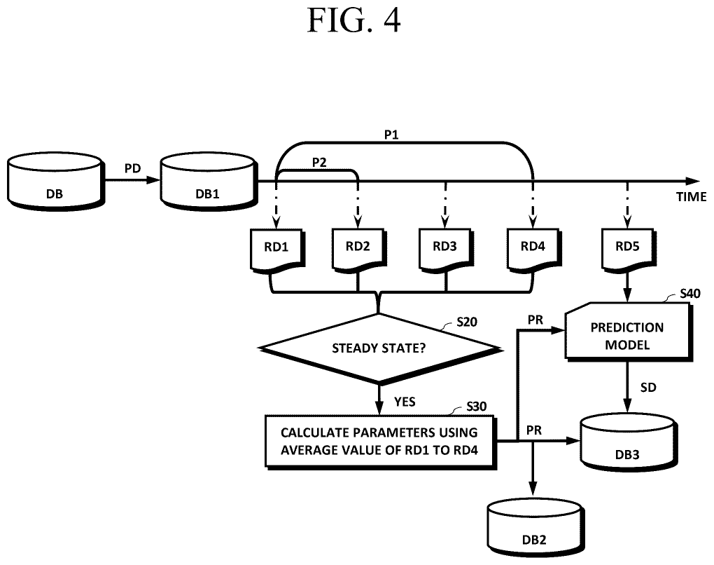

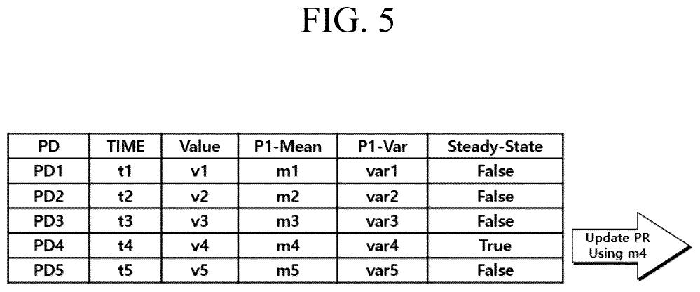

FIG. 4 is a diagram showing a digital twin creation method according to the exemplary embodiment of the present disclosure, and FIG. 5 is a table showing a steady state determination method according to an exemplary embodiment of the present disclosure.

Referring to FIG. 4, the digital twin creation server 10 may receive a plurality of pieces of refined plant data RD1, RD2, RD3, and RD4 acquired during a first period P1 from the first database DB1. As described above, the plurality of pieces of refined plant data RD1 to RD4 are acquired by processing plant data PD received from the legacy DB through the data processing part.

In the example of FIG. 4, each of the pieces of refined plant data RD1 to RD4 may be refined plant data acquired from the target facility FA at a specific time point, and time points at which the first refined plant data RD1 to the fourth refined plant data RD4 are acquired may sequentially have intervals of a second period P2.

The digital twin creation server 10 may determine whether the plurality of pieces of refined plant data RD1 to RD4 acquired during the first period P1 are in a steady state (S20). According to the exemplary embodiment, the digital twin creation server 10 may determine whether the plurality of pieces of refined plant data RD1 to RD4 are in a steady state by determining whether a variance of the plurality of pieces of refined plant data RD1 to RD4 acquired during the first period P1 is a predetermined value or less. In the example of FIG. 4, the first period P1 is 3 times longer than the second period P2, but embodiments of the present disclosure are not limited thereto. The first period P1 may be longer or shorter than 3 times the second period P2, and accordingly, the number of pieces of refined plant data included in the first period P1 may vary. As an example, the first period P1 may be 3 hours, and the second period P2 may be 15 minutes.

When the plurality of pieces of refined plant data RD1 to RD4 are in a steady state, the digital twin creation server 10 may calculate parameters PR using a mean value of the plurality of pieces of refined plant data RD1 to RD4 (S30). The digital twin creation server 10 may store the calculated parameters PR in the second database DB2 and reflect the calculated parameters PR in a prediction model.

Referring to the example of FIG. 5, the digital twin creation server 10 may receive the first refined plant data RD1 corresponding to a first time point t1, the second refined plant data RD2 corresponding to a second time point t2, the third refined plant data RD3 corresponding to a third time point t3, the fourth refined plant data RD4 corresponding to a fourth time point t4, and fifth refined plant data RD5 corresponding to a fifth time point t5, and the first refined plant data RD1 to the fifth refined plant data RD5 may have, as data values, a first value v1, a second value v2, a third value v3, a fourth value v4, and a fifth value v5, respectively. When the refined plant data is measured temperatures, each of the first value v1 to the fifth value v5 may represent a temperature value.

The digital twin creation server 10 may calculate a first-period mean value P1-mean and a first-period variation value P1-Var. In the example of FIG. 4, the first period P1 includes 4 pieces of plant data. Accordingly, the first-period mean value P1-Mean corresponding to the fourth refined plant data RD4 may be a mean value of the first value v1 to the fourth value v4 corresponding to the first period P1 before the fourth refined plant data RD4, and the first-period variation value P1-Var may be a variation value of the first value v1 to the fourth value v4 corresponding to the first period P1 before the fourth refined plant data RD4.

The digital twin creation server 10 may determine whether the first-period variation value P1-Var is a predetermined value or less and determine whether the refined plant data is in a steady state on the basis of the determination result. As an example, the digital twin creation server 10 may determine whether a fourth variation value Var4 corresponding to the first refined plant data RD1 to the fourth refined plant data RD4 is the predetermined value or less. When the fourth variation value Var4 is the predetermined value or less, the digital twin creation server 10 may determine whether the refined plant data is in a steady state, and acquire parameters PR using a fourth mean value m4 that is the first-period mean value P1-Mean of the first refined plant data RD1 to the fourth refined plant data RD4.

Referring back to FIG. 4, the digital twin creation server 10 may generate prediction data SD by inputting fifth refined plant data RD5 into the prediction model in which the parameters PR are reflected (S40). The digital twin creation server 10 may store the prediction data SD in the second database DB2 and create a digital twin by utilizing the prediction data SD.

According to the exemplary embodiment of the present disclosure, whether the target facility FA is in a steady state can be easily determined by determining whether the plurality of pieces of refined plant data of the first period P1 are in a steady state using whether a variation value of the plurality of pieces of refined plant data is a predetermined value or less. Also, refined plant data in a steady state is utilized to update the parameters PR such that parameters with minimized noise can be reflected in the prediction model.

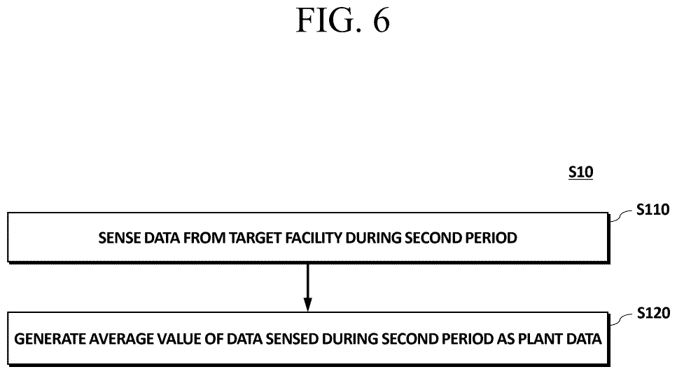

FIG. 6 is a flowchart showing the digital twin creation method according to the exemplary embodiment of the present disclosure. Specifically, FIG. 6 shows the operation S10 of receiving plant data in FIG. 3 in detail.

Referring to FIG. 6, the digital twin creation system 1 may sense the target facility FA during a second period (S110) and generate an average value of data sensed during the second period as refined plant data RD (S120).

According to the exemplary embodiment of the present disclosure, the digital twin creation system 1 does not directly generate results obtained by sensing the target facility FA as refined plant data RD but generate an average value of results obtained by sensing the target facility FA during a specific period as refined plant data RD. Therefore, it is possible to prevent plant data from having an incorrect value due to noise, and as a result, plant data to be reflected in a digital twin can be generated as accurate values.

According to an exemplary embodiment, the processor 100 implements a sliding-window steady-state gate. More specifically, plant data PD is acquired at a second period (P2) and buffered into a window of length first period (P1) where P1=N×P2 (N≥2). For each newly completed window, the steady state determiner 110 computes a variance value over the buffered samples and compares the variance with a sensor-specific threshold stored in the memory 200. When the variance is less than or equal to the threshold, the window is classified as steady state, and the parameter updater 120 is permitted to update model parameters; otherwise, parameter updates are withheld and previously validated parameters are retained. In some embodiments, a hysteresis policy is applied such that steady-state classification requires the variance condition to be satisfied for M consecutive windows (M≥2), which prevents chattering due to transient fluctuations.

To further reduce noise, the digital twin creation system 1 may, during each second period P2, compute and store in the first database DB1 the mean value of raw sensor readings collected within P2. The use of the P2-mean as the atomic “plant data” sample reduces the influence of high-frequency sensor spikes while preserving process dynamics that are relevant to parameter identification over P1.

By way of example and without limitation, consider P2=15 minutes and P1=3 hours (N=12). The steady state determiner 110 declares steady state only after the variance of 12 consecutive P2-means for a given sensor remains below the sensor's threshold for M=2 consecutive windows. Upon such declaration, the parameter updater 120 computes the window mean and updates PR={k0, Mcoke, U}. The prediction data generator 130 then evaluates the model to obtain Ttube and ΔP. If the interface part 140 detects that Ttube will exceed a safety limit within the next Δt, it sends a control command to decrease heater power by a predefined ramp and increase coolant flow for a hold period, after which normal operation is resumed. Throughout the sequence, the updated PR and the resulting SD are recorded in DB2, and the digital twin DT overlays the predicted Ttube distribution on AR2.

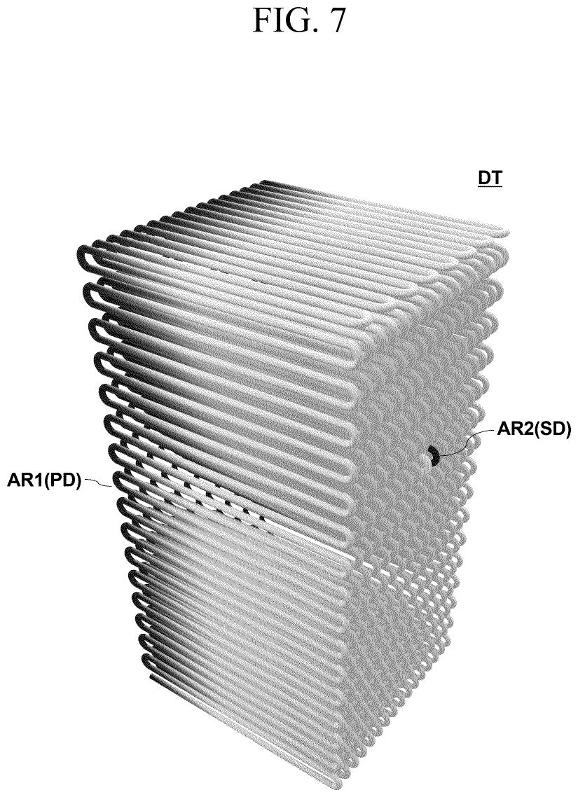

FIG. 7 is a view of a digital twin according to an exemplary embodiment of the present disclosure.

Referring to FIG. 7, a target facility may include a first area AR1 that is measurable by a sensor or the like, and a second area AR2 that is unmeasurable by a sensor or the like. The digital twin creation system 1 may generate plant data as a result of sensing the first area AR1 and update parameters depending on whether the sensed plant data is in a steady state. Also, the digital twin creation system 1 may generate prediction data SD on the basis of a prediction model of which the parameters have been updated and interfaces with the second area AR2 to correspond to the prediction data SD (e.g., changing the color of the second area AR2 to correspond to the prediction data), thereby creating a digital twin DT.

According to the exemplary embodiment of the present disclosure, since the digital twin creation system 1 adaptively changes parameters, information on the target facility can be reflected in the digital twin DT in real time, and as a result, the digital twin DT that matches the actual target facility can be created.

As shown in FIG. 7, the target facility may include a measurable first area AR1 and an unmeasurable second area AR2. The interface part 140 maps the prediction data SD to the digital twin DT by applying a visual overlay to AR2—e.g., color-coding T_{tube} across the geometry of AR2 or rendering a vector field for predicted composition gradients. The mapping function may use calibrated colormaps and threshold-based annotations (e.g., warning badges when a local value exceeds a limit), allowing an operator to visually localize process hotspots that are not directly instrumented. This visualization is updated at each second period P2 so that the DT remains synchronized with the target facility FA.

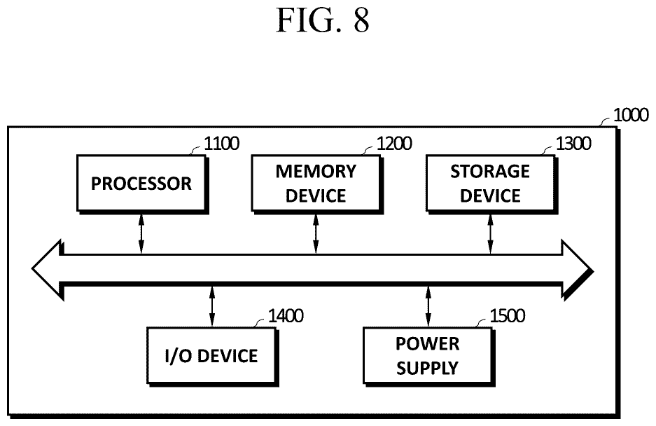

FIG. 8 is a block diagram showing a digital twin creation server according to an exemplary embodiment of the present disclosure.

Referring to FIG. 8, a digital twin creation server 1000 may include a processor 1100, a memory device 1200, a storage device 1300, an input/output (I/O) device 1400, and a power supply 1500. Meanwhile, although not shown in FIG. 8, the digital twin creation server 1000 may further include ports that may communicate with a video card, a sound card, a memory card, a Universal Serial Bus (USB) device, etc., or communicate with other electronic devices.

Like this, the processor 1100, the memory device 1200, the storage device 1300, the power supply 1500, and the I/O device 1400 included in the digital twin creation server 1000 may perform operations of the digital twin creation server 1000 according to exemplary embodiments based on the technical spirit of the present invention. Specifically, the operations of the digital twin creation server 1000 described above in FIGS. 1 to 7 may be operations performed by the processor 1100 on the basis of a computer program including at least one instruction stored in the memory device 1200 or the storage device 1300.

The processor 1100 may perform specific calculations or tasks. According to the exemplary embodiment, the processor 1100 may include at least one of a microprocessor, a CPU, a GPU, a NPU, a RAM, a ROM, a system bus, and an application processor. The processor 1100 may communicate with the memory device 1200, the storage device 1300, and the I/O device 1400 through a bus 1600 such as an address bus, a control bus, a data bus, and the like. According to the exemplary embodiment, the processor 1100 may also be connected to an expansion bus such as the peripheral component interconnect (PCI) bus.

The memory device 1200 may store data required for the digital twin creation server 1000 to operate. For example, the memory device 1200 may be implemented as a dynamic RAM (DRAM), a mobile DRAM, a static RAM (SRAM), a phase-change RAM (PRAM), a ferroelectric RAM (FRAM), a resistive RAM (RRAM), and/or a magnetoresistive RAM (MRAM). The storage device 1300 may include a SSD, an HDD, a compact disc (CD)-ROM, or the like. The memory device 1200 and the storage device 1300 may store a program for the digital twin creation method described above in FIGS. 1 to 7.

The I/O device 1400 may include an input device such as a keyboard, a keypad, a mouse, etc., and an output device such as a printer, a display, and the like. The power supply device 1500 may supply an operation voltage required for the digital twin creation server 1000 to operate.

According to the technical spirit of the present disclosure, parameters of a prediction model are updated on the basis of plant data in a steady state, and the updated parameters are utilized to generate prediction data. Therefore, changes in a target facility of which a digital twin has been created can be reflected in the prediction model in real time through the parameters, and as a result, the degree of synchronization of the digital twin with the target facility can increase.

While the embodiments above use variance as the steady-state criterion, additional filters (e.g., outlier rejection within the P1 window) may be applied in conjunction with the variance test to improve robustness without altering the decision rule. Moreover, the thresholds can be sensor-specific to reflect differences in sensor noise characteristics and installation locations within the target facility FA. The control interface of the interface part 140 may generate advisory messages instead of commands in installations where automatic actuation is restricted; in such cases, an operator may confirm a suggested setpoint change on the user terminal 20, after which the command is sent to the controller.

Exemplary embodiments have been disclosed in the drawings and specification. Although specific terms are used in this specification to describe the exemplary embodiments, these are only used for the purpose of describing the technical spirit of the present disclosure and are not used to limit the scope of the present disclosure described in the claims. Accordingly, those of ordinary skill in the art should understand that various modifications and other equivalent embodiments can be made based on the exemplary embodiments. Therefore, the technical scope of the present invention should be determined based on the following claims.

What is claimed is:

1. A non-transitory computer-readable medium storing instructions that, when executed by at least one processor, cause the at least one processor to perform operations comprising:
receiving data from a legacy database;
performing primary data processing on the data to obtain refined data;
storing the refined data in a first database; and
inputting the refined data stored in the first database into a steady-state determination module and storing, in a second database, model parameter update data derived based on output from the steady-state determination module.

2. The non-transitory computer-readable medium of claim 1, wherein the operations for the primary data processing are performed on plant data generated by sensing a target facility that is a target of a digital twin and stored in the legacy database.

3. The non-transitory computer-readable medium of claim 2, wherein the primary data processing removes abnormal data.

4. The non-transitory computer-readable medium of claim 1, wherein the instructions further cause the at least one processor to:
receive a plurality of pieces of plant data sequentially measured over time during a first period;
calculate a variation value of the plurality of pieces of plant data;
determine whether the variation value is less than or equal to a predetermined value; and
when the variation value is less than or equal to the predetermined value, determine that the plurality of pieces of plant data are in a steady state and store steady-state determination information in the second database.

5. The non-transitory computer-readable medium of claim 4, wherein the instructions further cause the at least one processor to:
calculate a mean value of the plurality of pieces of plant data;
acquire parameters from a prediction model using the calculated mean value; and
store the acquired parameters as updated parameters in the second database to be applied to the prediction model.

6. The non-transitory computer-readable medium of claim 4, wherein the instructions further cause the at least one processor to receive the plant data at intervals of a second period, the second period being shorter than the first period.

7. The non-transitory computer-readable medium of claim 6, wherein the instructions further cause the at least one processor to:
collect N pieces (N is a natural number of 2 or more) of the plant data corresponding to the first period by collecting the plant data at every second period;
calculate a mean value of the collected plant data;
acquire parameters from a prediction model using the calculated mean value; and
update the second database with the parameters by applying the acquired parameters to the prediction model.

8. The non-transitory computer-readable medium of claim 1, wherein the instructions further cause the at least one processor to:
input the refined data into a dynamic state model reflecting updated model parameters;
generate model prediction data; and
store the model prediction data in a third database.

9. The non-transitory computer-readable medium of claim 8, wherein the instructions further cause the at least one processor to:
generate reference prediction data by receiving the data from the legacy database; and
store, in the third database, a result of the generation as the reference prediction data separately from the model prediction data.

10. The non-transitory computer-readable medium of claim 9, wherein the instructions further cause the at least one processor to compare the reference prediction data and the model prediction data stored in the third database to verify a data processing portion.

11. A non-transitory computer-readable medium storing instructions that, when executed by at least one processor, cause the at least one processor to perform operations comprising:
receiving sensing data from a legacy database and removing noise;
determining whether plant data generated by sensing a target facility that is a target of a digital twin is in a steady state;
acquiring parameters by applying the plant data to a prediction model when the plant data is in the steady state, and applying the acquired parameters to the prediction model;
generating prediction data by inputting the plant data into the prediction model of which the parameters are updated; and
storing (i) refined data derived from the sensing data in a first database, (ii) the acquired parameters in a second database, and (iii) the prediction data in a third database.

12. A digital twin creation server comprising:
a memory storing a first database (DB1), a second database (DB2), and a third database (DB3) in mutually distinct address ranges; and
at least one processor configured to:
(a) obtain sensor measurements from a plurality of sensors of a target facility at a second period (P2);
(b) compute a P2-mean for each process variable and write the P2-means to DB1;
(c) maintain a sliding window of length P1=N×P2 (N≥2), compute a variance over the window, compare the variance with sensor-specific thresholds stored in the memory, and classify the window as steady state only when the comparison is satisfied for M consecutive windows (M≥2), and record steady-state information in DB2;
(d) when the window is steady, compute a window mean and solve mass-balance and energy-balance equations to acquire a parameter vector (PR) for a prediction model, and write PR with a timestamp and a window identifier to DB2;
(e) evaluate a dynamic-state model using PR and the plant data to generate prediction data (SD) including at least one unmeasured state variable, and write SD to DB3 together with an identifier of PR used; and
(f) execute (c)-(e) asynchronously with respect to (a)-(b) to avoid contention and to meet real-time latency for visualization and control.
